(19) United States
(12) Patent Application Publication
(10) Pub. No.: US 2026/0082521 A1
(43) Pub. Date: Mar. 19, 2026

(54) SERVER COOLING SYSTEM

(71) Applicant: MITSUBISHI HEAVY INDUSTRIES, LTD., Tokyo (JP)

(72) Inventors: Nobuhide Hara, Tokyo (JP); Yuichi OTANI, Tokyo (JP)

(73) Assignee: MITSUBISHI HEAVY INDUSTRIES, LTD., Tokyo (JP)

(21) Appl. No.: 19/108,528

(22) PCT Filed: Sep. 8, 2023
(86) PCT No.: PCT/JP2023/032872

§ 371 Date: Mar. 4, 2025

(30) Foreign Application Priority Data
Sep. 9, 2022 (JP) 2022-143625

(51) Int. Cl. H05K 7/20

(52) U.S. Cl. CPC H05K 7/20772

(57) ABSTRACT

A server cooling system includes a rack, a plurality of servers that are accommodated in the rack to be arranged in an up-down direction and each of which has a heat generating body, and a cooling device that is configured to cool each of the heat generating bodies. The cooling device includes a plurality of cold plates that are provided to correspond to the heat generating bodies of each server and are in contact with the corresponding heat generating bodies, a refrigerant supply path that is configured to supply a refrigerant to each of the cold plates, a refrigerant discharge path that is configured to discharge the refrigerant that has passed through each of the cold plates, and a cooling unit that is configured to cool the refrigerant that has passed through each of the refrigerant discharge paths and to introduce the refrigerant into the refrigerant supply path.

### TECHNICAL FIELD

The present disclosure relates to a server cooling system.

Priority is claimed on Japanese Patent Application No. 2022-143625, filed Sep. 9, 2022, the content of which is incorporated herein by reference.

### BACKGROUND ART

The server has memories and a heat generating body such as a GPU and a CPU chip. Examples of a method of cooling the heat generating body in the server include a rear door method (see, for example, Patent Document 1) of installing a cooling coil in a rack and blowing air to cool the heat generating body, and a chip cooling method (see, for example, Patent Document 2) of installing a heat receiving device on a chip (heat generating body) and supplying a refrigerant to the heat receiving device to cool the chip.

### CITATION LIST

### Patent Documents

Patent Document 1: Japanese U.S. Pat. No. 6,649,098
Patent Document 2: Japanese U.S. Pat. No. 5,949,924

### SUMMARY OF INVENTION

### Technical Problem

However, in the rear door method, for example, in a case of cooling a heat generating body having a high load of more than 100 W per chip, it is necessary to flow air having a large air volume. Therefore, the power consumption increases, and the cooling efficiency deteriorates. On the other hand, in the chip cooling method, it is necessary to install a cooling device for each heat generating body. Therefore, in a case where the number of heat generating bodies is large, the number of components is large, and the cooling system cannot be designed to be compact.

The present disclosure has been made in order to solve the above-described problems, and an object of the present disclosure is to provide a server cooling system that can efficiently cool a heat generating body while achieving compactness.

### Solution to Problem

In order to solve the above-described problem, a server cooling system according to the present disclosure includes at least one rack, a plurality of servers that are accommodated in the rack to be arranged in an up-down direction and each of which has a heat generating body, and a cooling device that is configured to cool each of the heat generating bodies, in which the cooling device includes a plurality of cold plates that are provided to correspond to the heat generating bodies of each of the plurality of servers and are in contact with the heat generating bodies corresponding to each of the plurality of cold plates, a plurality of refrigerant supply paths that are configured to supply a refrigerant to each of the plurality of cold plates, a plurality of refrigerant discharge paths that are configured to discharge the refrigerant that has passed through each of the plurality of cold plates, and a cooling unit that is configured to cool the refrigerant that has passed through each of the plurality of refrigerant discharge paths and to introduce the refrigerant into each of the plurality of refrigerant supply paths.

### Advantageous Effects of Invention

According to the server cooling system of the present disclosure, it is possible to efficiently cool the heat generating body while achieving compactness.

### BRIEF DESCRIPTION OF DRAWINGS

FIG. 1 A configuration diagram of a server cooling system according to a first embodiment of the present disclosure.

FIG. 2 A diagram showing an inside of a server according to the first embodiment of the present disclosure.

FIG. 3 A diagram showing an inside of a server according to a modification example of the first embodiment of the present disclosure.

FIG. 4 A configuration diagram of a server cooling system according to a second embodiment of the present disclosure as viewed obliquely.

FIG. 5 A configuration diagram of a server cooling system according to a second embodiment of the present disclosure as viewed from a side.

FIG. 6 A configuration diagram of a server cooling system according to a first modification example of the second embodiment of the present disclosure.

FIG. 7 A configuration diagram of a server cooling system according to a second modification example of the second embodiment of the present disclosure.

FIG. 8 A configuration diagram of a server cooling system according to a third modification example of the second embodiment of the present disclosure.

FIG. 9 A diagram showing the arrangement of a server cooling system according to a third embodiment of the present disclosure.

FIG. 10 A configuration diagram of a server cooling system according to a third embodiment of the present disclosure.

FIG. 11 A diagram showing the arrangement of a server cooling system according to a first modification example of the third embodiment of the present disclosure.

FIG. 12 A diagram showing the arrangement of a server cooling system according to a second modification example of the third embodiment of the present disclosure.

### DESCRIPTION OF EMBODIMENTS

### First Embodiment

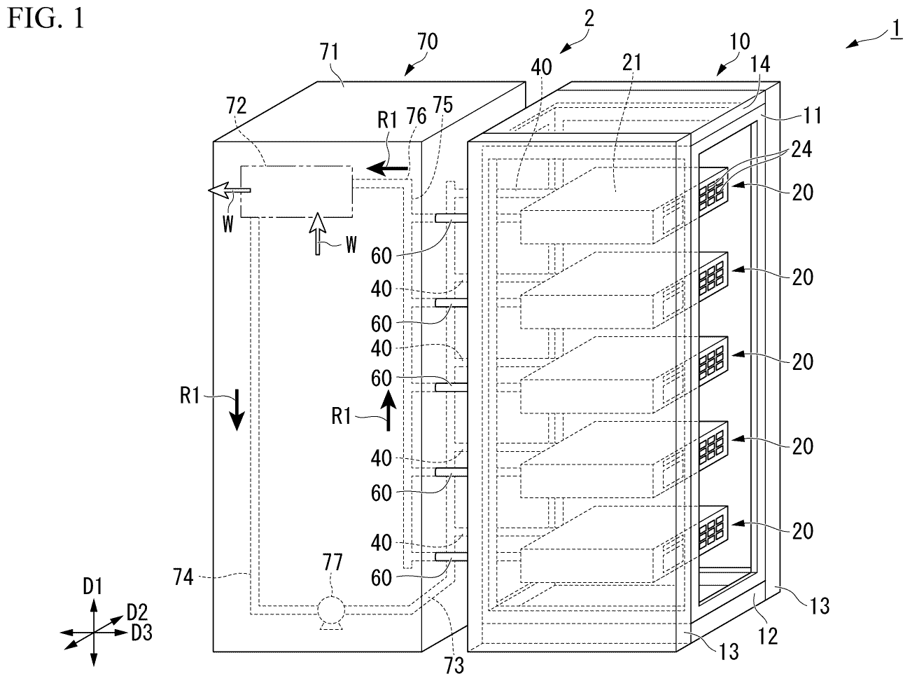

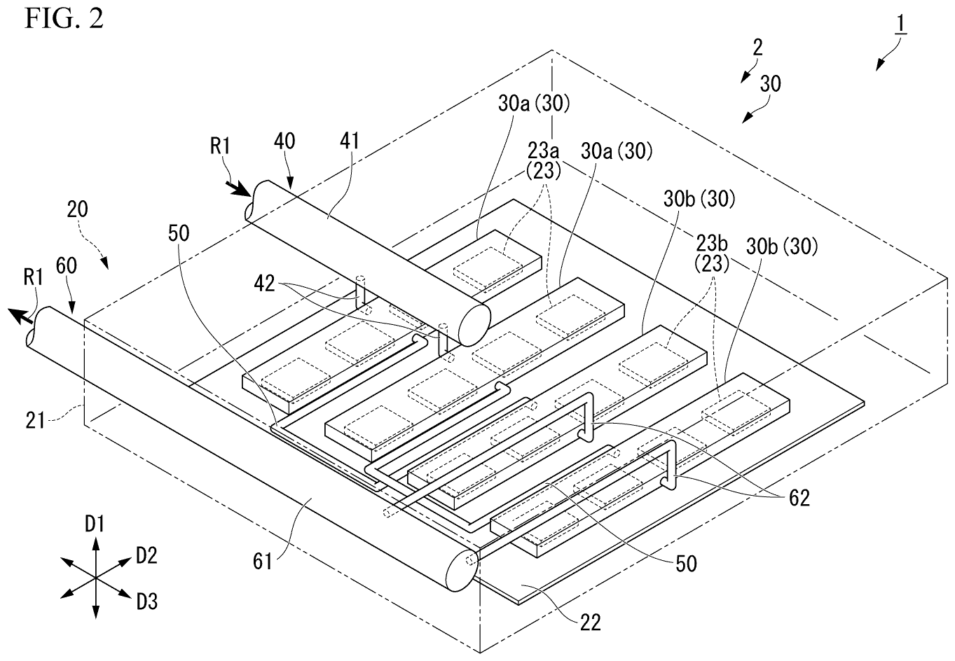

Hereinafter, a server cooling system 1 according to an embodiment of the present disclosure will be described with reference to FIGS. 1 and 2. The server cooling system 1 is used for, for example, a server 20 of a data center.

As shown in FIG. 1, a server cooling system 1 includes at least one rack 10, a plurality of servers 20, and a cooling device 2.

### Rack

The rack 10 has a shape extending in an up-down direction D1. The rack 10 can accommodate a plurality of servers 20 arranged in the up-down direction D1. The rack 10 includes a frame 11, a bottom plate 12, a side plate 13, and a top plate 14.

The frame 11 has a rectangular parallelepiped shape.

The bottom plate 12 is provided at the bottom portion of the frame 11 and forms the bottom portion of the rack 10.

The side plate 13 is provided on a side portion of the frame 11. The side plates 13 are provided to face each other in a direction perpendicular to the up-down direction D1. The lower ends of the pair of side plates 13 are connected to each other by the bottom plate 12.

The top plate 14 is provided on the upper portion of the frame 11. The top plate 14 connects upper ends of the pair of side plates 13 to each other.

Hereinafter, a direction in which the pair of side plates 13 face each other will be referred to as a “left-right direction D2”, and a direction perpendicular to the up-down direction D1 and the left-right direction D2 will be referred to as a “front-rear direction D3”.

### Server

The plurality of servers 20 are accommodated in the rack 10 to be arranged in the up-down direction D1. In the present embodiment, for example, five servers 20 are accommodated in the rack 10. The number of servers 20 accommodated in the rack 10 can be appropriately changed. As shown in FIG. 2, the server 20 includes a casing 21, a substrate 22, and a heat generating body 23.

### Casing

The casing 21 is formed in a rectangular parallelepiped shape extending in a horizontal direction. The casing 21 is fixed to the side plate 13. A plurality of ventilation holes 24 penetrating the casing 21 are provided on a front surface and a rear surface of the casing 21 (see FIG. 1). A substrate 22 and a heat generating body 23 are accommodated in the casing 21.

### Substrate

The substrate 22 is a printed substrate on which a plurality of electronic components are installed. The substrate 22 extends in the horizontal direction.

### Heat Generating Body

The heat generating body 23 is an electronic component installed on the substrate 22. A plurality of heat generating bodies 23 are provided on the substrate 22. The plurality of heat generating bodies 23 include a low-temperature heat generating body 23a having a relatively small amount of heat generation and a high-temperature heat generating body 23b having a relatively large amount of heat generation.

The low-temperature heat generating body 23a is, for example, a low load heat generating body 23 having a power of equal to or less than 100 W. Examples of the low-temperature heat generating body 23a include memories and the like. A plurality of low-temperature heat generating bodies 23a are provided, for example, on the rear side in the front-rear direction D3. The plurality of low-temperature heat generating bodies 23a are disposed to form a row extending in the left-right direction D2. The columns of the low-temperature heat generating bodies 23a are formed in two rows arranged in the front-rear direction D3.

The high-temperature heat generating body 23b is, for example, a heat generating body 23 having a high load of more than 100 W. Examples of the high-temperature heat generating body 23b include chips such as a CPU and a GPU. A plurality of high-temperature heat generating bodies 23b are provided, for example, on the front side in the front-rear direction D3. The plurality of high-temperature heat generating bodies 23b are disposed to form a row extending in the left-right direction D2. The high-temperature heat generating bodies 23b are formed in two rows arranged in the front-rear direction D3.

### Cooling Device

The cooling device 2 can cool each heat generating body 23 in the server 20. The cooling device 2 includes a cold plate 30, a refrigerant supply path 40, a refrigerant connection path 50, a refrigerant discharge path 60, and a cooling unit 70.

### Cold Plate

A plurality of cold plates 30 are provided to correspond to the heat generating bodies 23 of the respective servers 20. The cold plate 30 comes into contact with the corresponding heat generating body 23.

Each cold plate 30 is provided to be in contact with the plurality of heat generating bodies 23. The cold plate 30 is formed in a rectangular plate shape extending in a horizontal direction. The cold plate 30 extends in the left-right direction D2. The cold plate 30 is manufactured by, for example, an additive manufacturing (AM) technology. A groove portion (not shown) is formed on a surface of the cold plate 30 facing the heat generating body 23, and the heat generating body 23 is fitted into the groove. A refrigerant R1 for cooling the heat generating body 23 is sealed inside the cold plate 30.

Examples of the refrigerant R1 include water and Fluorinert. The refrigerant R1 is supplied to the cold plate 30 from the refrigerant supply path 40, and the refrigerant R1 is discharged from the cold plate 30 through the refrigerant discharge path 60.

The plurality of cold plates 30 include a single-phase cold plate 30a and a boiling cold plate 30b.

In the single-phase cold plate 30a, the refrigerant R1 flows in a single-phase state. In the present embodiment, the single-phase cold plate 30a is provided on the refrigerant supply path 40 side with respect to the boiling cold plate 30b in the flow direction of the refrigerant R1. The single-phase cold plate 30a is provided in each row of the low-temperature heat generating bodies 23a. The single-phase cold plate 30a is disposed along a row of the corresponding low-temperature heat generating bodies 23a. In the single-phase cold plate 30a, the refrigerant R1 receives heat from the low-temperature heat generating body 23a and flows in a liquid phase state without boiling.

The boiling cold plate 30b is connected in series with the single-phase cold plate 30a in a direction in which the refrigerant R1 flows. The boiling cold plate 30b is provided in each column of the high-temperature heat generating bodies 23b. The boiling cold plate 30b is disposed along a column of the corresponding high-temperature heat generating body 23b. In the boiling cold plate 30b, the refrigerant R1 receives heat from the high-temperature heat generating body 23b and boils. Therefore, in the boiling cold plate 30b, the refrigerant R1 flows in a two-phase state of a liquid phase and a gas phase.

### Refrigerant Supply Path

The refrigerant supply path 40 supplies the refrigerant R1 to each cold plate 30. A plurality of refrigerant supply paths 40 are provided in the up-down direction D1. The refrigerant supply path 40 is provided for each server 20. The refrigerant supply path 40 includes a refrigerant supply header 41 and a refrigerant supply branch pipe 42.

The refrigerant supply header 41 is connected to the cooling unit 70. The refrigerant R1 is supplied from the cooling unit 70 to the refrigerant supply header 41. The refrigerant supply header 41 penetrates the casing 21 of the server 20.

A plurality of refrigerant supply branch pipes 42 are provided in each refrigerant supply header 41. The refrigerant supply branch pipe 42 is connected to the plurality of cold plates 30 in the casing 21. The refrigerant supply branch pipe 42 supplies the refrigerant R1 from the refrigerant supply header 41 to each cold plate 30 of the connection destination. In the present embodiment, the refrigerant supply branch pipe 42 is connected to the single-phase cold plate 30a among the plurality of cold plates 30. The refrigerant supply branch pipe 42 is provided one by one for each single-phase cold plate 30a. The refrigerant supply branch pipe 42 is connected to a center portion of the corresponding single-phase cold plate 30a in the longitudinal direction.

### Refrigerant Connection Path

The refrigerant connection path 50 connects a center portion of the single-phase cold plate 30a in the longitudinal direction and a center portion of the boiling cold plate 30b in the longitudinal direction. In the present embodiment, the refrigerant connection path 50 guides the refrigerant R1 from the single-phase cold plate 30a to the boiling cold plate 30b.

### Refrigerant Discharge Path

The refrigerant discharge path 60 discharges the refrigerant R1 that has passed through each cold plate 30. A plurality of refrigerant discharge paths 60 are provided in the up-down direction D1. The refrigerant discharge path 60 is provided for each server 20. The refrigerant discharge path 60 includes a refrigerant discharge header 61 and a refrigerant discharge branch pipe 62.

The refrigerant discharge header 61 is connected to the cooling unit 70. The refrigerant discharge header 61 penetrates the casing 21 of the server 20.

A plurality of refrigerant discharge branch pipes 62 are provided in each refrigerant discharge header 61. The refrigerant discharge branch pipe 62 is connected to the plurality of cold plates 30 in the casing 21. The refrigerant discharge branch pipe 62 discharges the refrigerant R1 from each cold plate 30 of the connection destination to the refrigerant discharge header 61. The refrigerant R1 discharged to the refrigerant discharge header 61 is guided to the cooling unit 70. In the present embodiment, the refrigerant discharge branch pipe 62 is connected to the boiling cold plate 30b among the plurality of cold plates 30. The refrigerant discharge branch pipe 62 is provided one by one for each boiling cold plate 30b. The refrigerant discharge branch pipe 62 is connected to a center portion of the corresponding boiling cold plate 30b in the longitudinal direction. For one server 20, it is desirable that the connection port between the refrigerant discharge branch pipe 62 and the cold plate 30 is positioned above the connection port between the refrigerant supply branch pipe 42 and the cold plate 30.

### Cooling Unit

The cooling unit 70 cools the refrigerant R1 that has passed through each refrigerant discharge path 60 and introduces the cooled refrigerant R1 into each refrigerant supply path 40. The cooling unit 70 is, for example, a vertically placed cooling water circulation device (coolant distribution unit (CDU)). From the viewpoint of reducing the pressure loss of the refrigerant R1 in the cooling cycle of the cooling device 2, it is desirable that the cooling unit 70 is disposed close to the rack 10. The cooling unit 70 includes a cooling unit casing 71, a heat exchanger 72, a first main header 73, a first connecting pipe 74, a second main header 75, a second connecting pipe 76, and a pump 77.

A heat exchanger 72, a first main header 73, a first connecting pipe 74, a second main header 75, a second connecting pipe 76, and a pump 77 are accommodated in the cooling unit casing 71. In the present embodiment, the cooling unit casing 71 is formed in a rectangular parallelepiped shape extending in the up-down direction D1.

The heat exchanger 72 is a condenser that cools and condenses the refrigerant R1 from each refrigerant discharge path 60. Cooling water W is supplied to the heat exchanger 72 of the present embodiment. The heat exchanger 72 cools the refrigerant R1 by performing heat exchange with the cooling water W and the refrigerant R1. The heat exchanger 72 is provided in an upper portion of the cooling unit casing 71.

The first main header 73 is connected to the heat exchanger 72. A plurality of refrigerant supply paths 40 are connected to the first main header 73. The first main header 73 guides the refrigerant R1 cooled by the heat exchanger 72 to each refrigerant supply path 40. The first main header 73 extends in the up-down direction D1. In the present embodiment, a lower end of the first main header 73 is connected to the heat exchanger 72 and the first connecting pipe 74.

The second main header 75 is connected to the heat exchanger 72. A plurality of refrigerant discharge paths 60 are connected to the second main header 75. The second main header 75 guides the refrigerant R1, which has passed through each cold plate 30 and has been heated, and has been discharged through each refrigerant discharge path 60, to the heat exchanger 72. The second main header 75 extends in the up-down direction D1. In the present embodiment, the upper end of the second main header 75 is connected to the heat exchanger 72 and the second connecting pipe 76.

The pump 77 pumps the refrigerant R1 cooled by the heat exchanger 72 toward each refrigerant supply path 40. The pump 77 is provided in the first connecting pipe 74 at a lower portion in the cooling unit casing 71.

### Circulation of Refrigerant

Next, the circulation of the refrigerant R1 in the server cooling system 1 will be described.

First, the liquid phase refrigerant R1 in the cooling unit 70 is pumped by the pump 77 and is distributed to each refrigerant supply path 40 by the first main header 73. The refrigerant R1 is further distributed to each refrigerant supply branch pipe 42 by the refrigerant supply header 41 and is distributed to the cold plate 30 of the connection destination. In the cold plate 30, the refrigerant R1 performs heat exchange with the heat generating body 23. As a result, the heat generating body 23 is cooled, and the refrigerant R1 is heated.

In the present embodiment, the refrigerant R1 from the refrigerant supply branch pipe 42 is first supplied to the single-phase cold plate 30a. In the single-phase cold plate 30a, the refrigerant R1 performs heat exchange with the low-temperature heat generating body 23a in a liquid phase. As a result, the low-temperature heat generating body 23a is cooled, and the refrigerant R1 is heated.

Thereafter, the refrigerant R1 is supplied to the downstream boiling cold plate 30b through the refrigerant connection path 50. In the boiling cold plate 30b, the refrigerant R1 performs heat exchange with the high-temperature heat generating body 23b. As a result, the high-temperature heat generating body 23b is cooled, and the refrigerant R1 is heated. In this case, a part of the refrigerant R1 in the boiling cold plate 30b boils and evaporates due to the heat of the high-temperature heat generating body 23b. Therefore, in the boiling cold plate 30b, the refrigerant R1 is present in two phases of a liquid phase and a gas phase.

The refrigerant R1 that has passed through the cold plate 30 is returned to the cooling unit 70 through the refrigerant discharge path 60. The refrigerant R1 discharged through each refrigerant discharge path 60 is collected in the second main header 75. The refrigerant R1 in the second main header 75 is guided to the heat exchanger 72 through the second connecting pipe 76.

In the heat exchanger 72, heat exchange is performed by the refrigerant R1 and the cooling water W. As a result, the refrigerant R1 heated by the cold plate 30 is cooled. As a result, the refrigerant R1 in the gas phase is condensed to be in the liquid phase. The liquid phase refrigerant R1 in the heat exchanger 72 is guided again to the first main header 73 by the first connecting pipe 74 and is distributed to each refrigerant supply path 40. In this way, the refrigerant R1 circulates in the server cooling system 1.

### Operations and Effects

With the server cooling system 1 according to the present embodiment, the following operations and effects are exhibited.

In the present embodiment, the server cooling system 1 includes a cooling device 2 capable of cooling each heat generating body 23. The cooling device 2 includes a cold plate 30, a refrigerant supply path 40, a refrigerant discharge path 60, and a cooling unit 70. A plurality of cold plates 30 are provided to correspond to the heat generating bodies 23 of the respective servers 20 and are in contact with the corresponding heat generating bodies 23. The refrigerant supply path 40 supplies the refrigerant R1 to each cold plate 30. The refrigerant discharge path 60 discharges the refrigerant R1 that has passed through each cold plate 30. The cooling unit 70 cools the refrigerant R1 that has passed through each refrigerant discharge path 60 and introduces the refrigerant R1 into the refrigerant supply path 40.

The refrigerant R1 performs heat exchange with the heat generating body 23 in each cold plate 30 and absorbs heat of the heat generating body 23. As a result, the heat generating body 23 is cooled, and the refrigerant R1 is heated. In the present embodiment, the heated refrigerant R1 is guided to the cooling unit 70 through each refrigerant discharge path 60. The refrigerant R1 is cooled by the cooling unit 70 and is supplied to each cold plate 30 again through the refrigerant supply path 40. As described above, the refrigerant R1 heated by each cold plate 30 is collectively cooled by the cooling unit 70. As described above, according to the present embodiment, the heat generating body 23 can be efficiently cooled while achieving compactness.

In the present embodiment, each cold plate 30 is provided to be in contact with the plurality of heat generating bodies 23. The plurality of cold plates 30 include a single-phase cold plate 30a in which the refrigerant R1 flows in a single-phase state and a boiling cold plate 30b in which the refrigerant R1 is boiled and the refrigerant R1 flows in a two-phase state of a liquid phase and a gas phase. The boiling cold plate 30b is connected in series with the single-phase cold plate 30a in a direction in which the refrigerant R1 flows.

With the above-described configuration, the cold plate 30 is in contact with the plurality of heat generating bodies 23. Therefore, the number of cold plates 30 can be reduced as compared with a case where one cold plate 30 is provided for each heat generating body 23. Therefore, the number of components of the server cooling system 1 can be reduced. Further, the plurality of cold plates 30 include a single-phase cold plate 30a and a boiling cold plate 30b connected in series. As a result, the server cooling system 1 can perform the heat exchange between the refrigerant R1 and the heat generating body 23 in a stepwise manner. As a result, the server cooling system 1 can use the refrigerant R1 in a cascaded manner in accordance with the disposition of the heat generating body 23 to be cooled. Therefore, the cooling efficiency of the server cooling system 1 can be further improved.

In the present embodiment, the single-phase cold plate 30a is provided on the refrigerant supply path 40 side with respect to the boiling cold plate 30b, and the refrigerant R1 flows in a liquid phase state.

In the above configuration, in the single-phase cold plate 30a, the refrigerant R1 performs heat exchange with the heat generating body 23 in a liquid phase state. Thereafter, the refrigerant R1 passes through the single-phase cold plate 30a and is supplied to the boiling cold plate 30b. The refrigerant R1 receives heat from the heat generating body 23 in the boiling cold plate 30b, boils, and evaporates. As a result, in the boiling cold plate 30b, the heat of vaporization of the refrigerant R1 is taken away from the heat generating body 23, and thus the heat generating body 23 is strongly cooled.

In the present embodiment, a single-phase cold plate 30a is provided on a low-temperature heat generating body 23a such as memories, and a boiling cold plate 30b is provided on a high-temperature heat generating body 23b such as a chip of a CPU or a GPU. Therefore, the low-temperature heat generating body 23a can be cooled with the refrigerant R1 in the liquid phase, and then the high-temperature heat generating body 23b can be cooled by vaporization of the refrigerant R1. Therefore, the server cooling system 1 can sufficiently and efficiently cool the heat generating body 23 having a different amount of heat generation.

### Modification Example of First Embodiment

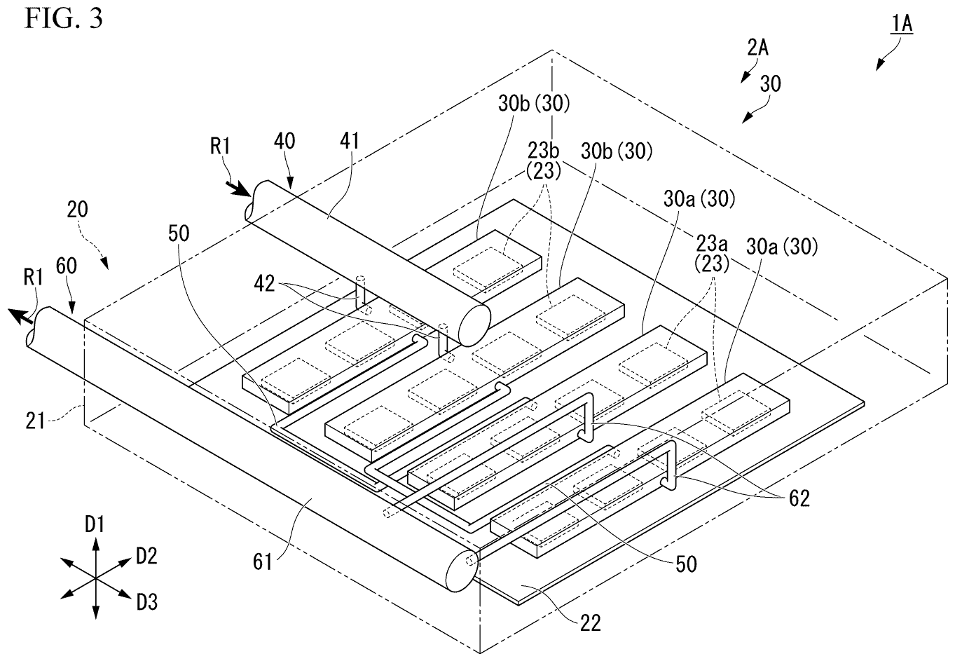

Next, a server cooling system 1A according to a modification example of the first embodiment will be described with reference to FIG. 3.

As shown in FIG. 3, in the cooling device 2A of the present modification example, a plurality of low-temperature heat generating bodies 23a are provided, for example, on the front side in the front-rear direction D3. A plurality of high-temperature heat generating bodies 23b are provided, for example, on the rear side in the front-rear direction D3. Therefore, among the plurality of cold plates 30, the single-phase cold plate 30a is provided on the front side in the front-rear direction D3, and the boiling cold plate 30b is provided on the rear side in the front-rear direction D3.

A refrigerant supply path 40 is connected to the boiling cold plate 30b. In the boiling cold plate 30b, the refrigerant R1 supplied from the refrigerant supply path 40 receives heat from the high-temperature heat generating body 23b and boils. Therefore, in the boiling cold plate 30b, the refrigerant R1 flows in a two-phase state of a liquid phase and a gas phase. The liquid-phase refrigerant R1 is completely changed into a gas phase by the boiling cold plate 30b.

In the present modification example, the single-phase cold plate 30a is provided on the refrigerant discharge path 60 side with respect to the boiling cold plate 30b in the flow direction of the refrigerant R1. A refrigerant discharge path 60 is connected to the single-phase cold plate 30a. The refrigerant R1 that has completely vaporized after passing through the boiling cold plate 30b is supplied to the single-phase cold plate 30a. In the single-phase cold plate 30a, the refrigerant R1 flows in a gas phase state.

With the server cooling system 1A of the present modification example, the following operations and effects are exhibited.

In the present modification example, the single-phase cold plate 30a is provided on the refrigerant discharge path 60 side with respect to the boiling cold plate 30b, and the refrigerant R1 flows in a gas phase state.

In the above-described configuration, in the boiling cold plate 30b, the working fluid receives heat from the heat generating body 23, boils, and evaporates. Thereafter, the refrigerant R1 in the gas phase is supplied to the single-phase cold plate 30a. Therefore, the refrigerant R1 in a gas phase flows in the single-phase cold plate 30a. As a result, the refrigerant R1 flows at a high flow velocity in the single-phase cold plate 30a. Therefore, the low-temperature heat generating body 23a connected to the single-phase cold plate 30a is cooled more efficiently.

### Second Embodiment

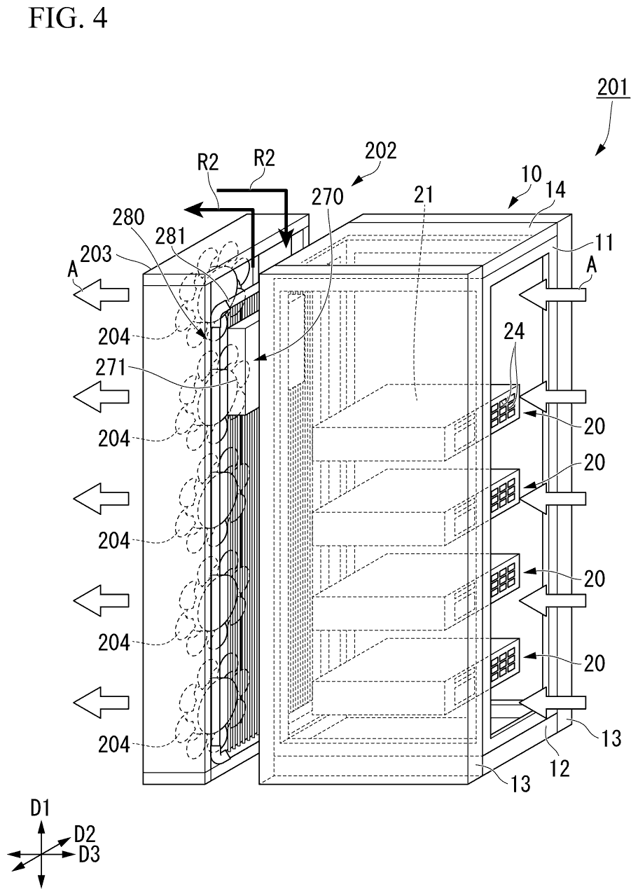

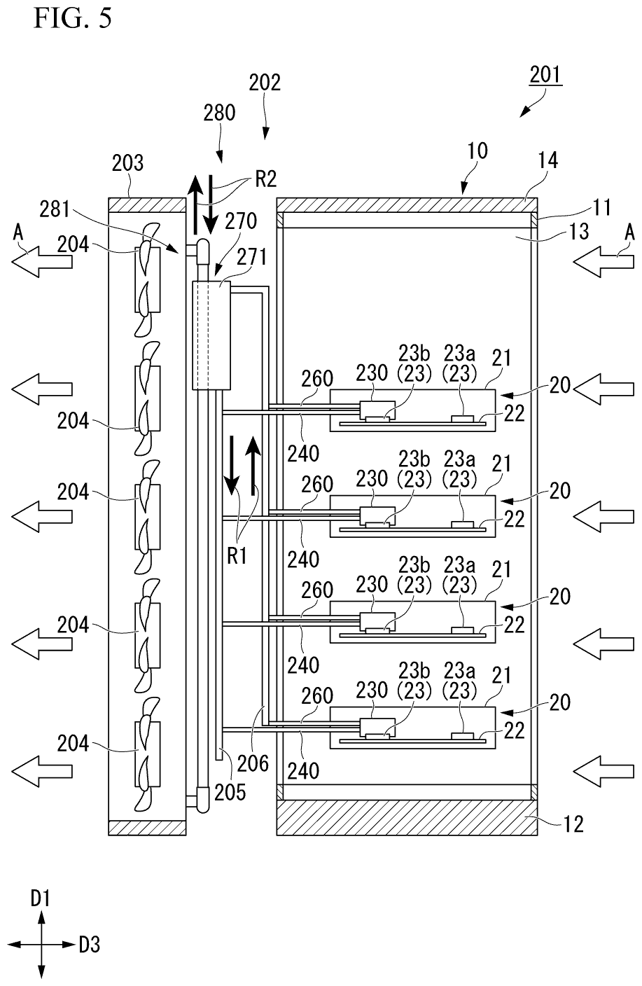

Hereinafter, a server cooling system 201 according to a second embodiment of the present disclosure will be described with reference to FIGS. 4 and 5. The same configurations as those in the first embodiment described above are designated by the same names and the same reference signs, and descriptions thereof will be appropriately omitted.

### Server Cooling System

As shown in FIGS. 4 and 5, the server cooling system 201 of the present embodiment includes a rack 10, a plurality of servers 20, and a cooling device 202. In the present embodiment, a plurality of (for example, four) servers 20 are provided in the upper portion of the rack 10 with a space. Each server 20 has a plurality of heat generating bodies 23. The plurality of heat generating bodies 23 include a low-temperature heat generating body 23a and a high-temperature heat generating body 23b.

In FIG. 4, a part of the configuration of the cooling device 202 is omitted.

### Cooling Device

The cooling device 202 includes a cold plate 230, a refrigerant supply path 240, a refrigerant discharge path 260, a cooling unit 270, a fan casing 203, a fan 204, a second cooling unit 280, a first connection header 205, and a second connection header 206.

### Cold Plate

A plurality of cold plates 230 are provided to correspond to the heat generating bodies 23 of the respective servers 20. The cold plate 230 is in contact with the corresponding heat generating body 23. In the present embodiment, the cold plate 230 is provided in the high-temperature heat generating body 23b among the heat generating bodies 23.

### Refrigerant Supply Path

The refrigerant supply path 240 is provided for each server 20. The refrigerant supply path 240 is connected to each corresponding cold plate 230 and supplies the refrigerant R1 from the cooling unit 270 to each cold plate 230. In the present embodiment, the refrigerant supply path 240 extends in the horizontal direction.

### Refrigerant Discharge Path

The refrigerant discharge path 260 is provided for each server 20. The refrigerant discharge path 260 is connected to each corresponding cold plate 230 and discharges the refrigerant R1 that has passed through each cold plate 230, to the cooling unit 270.

In addition, for one server 20, it is desirable that the connection port between the refrigerant discharge path 260 and the cold plate 230 is positioned above the connection port between the refrigerant supply path 240 and the cold plate 230.

### Cooling Unit

The cooling unit 270 cools the refrigerant R1 that has passed through each refrigerant discharge path 260 and introduces the refrigerant R1 into the refrigerant supply path 240. A detailed configuration of the cooling unit 270 will be described later.

Fan Casing

The fan casing 203 is disposed behind the rack 10. The fan casing 203 is formed in a rectangular parallelepiped shape extending in the up-down direction D1, and is open on both sides in the front-rear direction D3.

### Fan

A plurality of fans 204 are provided in the fan casing 203 to be arranged in the up-down direction D1. The fan 204 is provided in the rack 10. The fan 204 is provided for at least each server 20 and is disposed to face the corresponding server 20 in the front-rear direction D3. In the present embodiment, the fan 204 is also disposed at a position in the up-down direction D1 overlapping with a space in which the server 20 is not disposed in the upper portion of the rack 10 and the front-rear direction D3. The fan 204 draws in the air A so that the air A passes through the heat generating body 23 in the server 20.

Second Cooling Unit

The second cooling unit 280 is provided between the rack 10 and the fan 204. The second cooling unit 280 cools the air A that has passed through the heat generating body 23. The second cooling unit 280 includes a cooling coil 281.

### Cooling Coil

The cooling coil 281 is installed in an opening on the front side of the fan casing 203. The cooling coil 281 extends in the up-down direction D1 and the left-right direction D2. The cooling coil 281 is, for example, a fin tube type cooling coil. A second refrigerant R2 that performs heat exchange with the air A around the second cooling unit 280 flows through the cooling coil 281. Examples of the second refrigerant R2 include water.

### Configuration of Cooling Unit

The cooling unit 270 is provided in the cooling coil 281, performs heat exchange with the refrigerant R1 and the second refrigerant R2 flowing through the cooling coil 281, and cools the refrigerant R1. The cooling unit 270 has a jacket 271.

### Jacket

The jacket 271 is disposed at a position in the up-down direction D1 overlapping with a space in which the server 20 is not disposed in the upper portion of the rack 10 and the front-rear direction D3. A part of the cooling coil 281 is disposed inside the jacket 271. The refrigerant supply path 240 and the refrigerant discharge path 260 are connected to the jacket 271 through a first connection header 205 and a second connection header 206, which will be described later. The refrigerant R1 discharged through the refrigerant discharge path 260 is supplied into the jacket 271. In the jacket 271, the heat exchange is performed between the refrigerant R1 and the second refrigerant R2 in the cooling coil 281, and the refrigerant R1 is cooled. The refrigerant R1 cooled in the jacket 271 is supplied from each refrigerant supply path 240 to each server 20.

### First Connection Header

The first connection header 205 connects the jacket 271 and the plurality of refrigerant supply paths 240. The first connection header 205 guides the refrigerant R1 cooled in the jacket 271 to each refrigerant supply path 240. The first connection header 205 extends in the up-down direction D1.

### Second Connection Header

The second connection header 206 connects the jacket 271 and the plurality of refrigerant discharge paths 260. The second connection header 206 guides the refrigerant R1, which has passed through each cold plate 30 and has been heated and which has been discharged through each refrigerant discharge path 260, into the jacket 271. The second connection header 206 extends in the up-down direction D1.

### Circulation of Refrigerant

Next, the circulation of the refrigerant R1 in the server cooling system 201 will be described.

First, the refrigerant R1 in the jacket 271 is distributed to each refrigerant supply path 240 by the first connection header 205. The refrigerant R1 is supplied to the cold plate 230 connected to each refrigerant supply path 240. In the cold plate 230, the refrigerant R1 performs heat exchange with the heat generating body 23. As a result, the heat generating body 23 is cooled, and the refrigerant R1 is heated.

The refrigerant R1 that has passed through each cold plate 230 is collected in the second connection header 206 by the refrigerant discharge path 260. Then, the refrigerant R1 is returned to the jacket 271.

In the jacket 271, heat exchange is performed by the refrigerant R1 and the second refrigerant R2. As a result, the refrigerant R1 heated by the cold plate 230 is cooled. The liquid phase refrigerant R1 in the jacket 271 is distributed again to each refrigerant supply path 240. In this way, the refrigerant R1 circulates in the server cooling system 201.

The refrigerant R1 may be boiled and vaporized in the cold plate 230, may be condensed in the jacket 271, and may circulate in the cycle of the server cooling system 201 in two phases of a liquid phase and a gas phase. In this case, the refrigerant R1 is naturally circulated in the server cooling system 201 by the upward flow of the refrigerant R1 in the gas phase generated in the cold plate 230. On the other hand, the refrigerant R1 may circulate in the cycle of the server cooling system 201 in a single phase without boiling in the cold plate 230. In this case, a pump (not shown) that pumps the refrigerant R1 may be installed in the server cooling system 201, for example, in the first connection header 205 to forcibly circulate the refrigerant R1.

### Operations and Effects

With the server cooling system 201 according to the present embodiment, the following operations and effects are exhibited.

In the present embodiment, the cooling device 202 includes a fan 204 and a second cooling unit 280. The fan 204 is installed in the rack 10 and draws in the air A to pass through the heat generating body 23. The second cooling unit 280 is provided between the rack 10 and the fan 204 and cools the air A that has passed through the heat generating body 23. The second cooling unit 280 has a cooling coil 281 through which a second refrigerant R2 that performs heat exchange with the air A around the second cooling unit 280 flows.

According to the above configuration, the server cooling system 201 can draw in the air A by the fan 204 and pass the air A through the heat generating body 23. As a result, the server cooling system 201 can cool the heat generating body 23 with both the refrigerant R1 in the cold plate 230 and the air A drawn in by the fan 204.

For example, as in the present embodiment, by installing the cold plate 230 on the high-temperature heat generating body 23b among the heat generating bodies 23, the server cooling system 201 can cool the high-temperature heat generating body 23b by both the refrigerant R1 and the air A drawn in by the fan 204. Therefore, the server cooling system 201 can cool both the low-temperature heat generating body 23a and the high-temperature heat generating body 23b with a set value of an air volume that is enough to cool only the low-temperature heat generating body 23a among the heat generating bodies 23. Therefore, the server cooling system 201 can reduce the power consumption required to drive the fan 204. Further, since the noise of the fan 204 is also reduced, the working environment is improved.

In the present embodiment, the cooling unit 270 is provided in the cooling coil 281 and performs heat exchange with the refrigerant R1 and the second refrigerant R2.

According to the above configuration, the refrigerant R1 heated by performing heat exchange with the heat generating body 23 is cooled by the second refrigerant R2 in the cooling coil 281. Therefore, it is not necessary to separately provide a device for cooling the heated refrigerant R1. Therefore, it is possible to achieve the size reduction of the server cooling system 201 and to realize the space saving.

In the present embodiment, the case where the refrigerant supply path 240 extends in the horizontal direction has been described, but the present invention is not limited thereto. However, in a case where the refrigerant R1 is naturally circulated in the cycle of the server cooling system 201 by convection as in the present embodiment, the refrigerant supply path 240 needs to be formed in a shape extending in the horizontal direction or in a descending gradient shape extending downward toward the front side in the front-rear direction D3.

However, in a case where the refrigerant R1 is forcibly circulated by, for example, a pump (not shown), the refrigerant R1 can circulate in the cycle of the server cooling system 201 even in a case where the refrigerant supply path 240 is formed, for example, in an ascending gradient shape that extends toward the front side in the front-rear direction D3 and is positioned upward.

First Modification Example of Second Embodiment

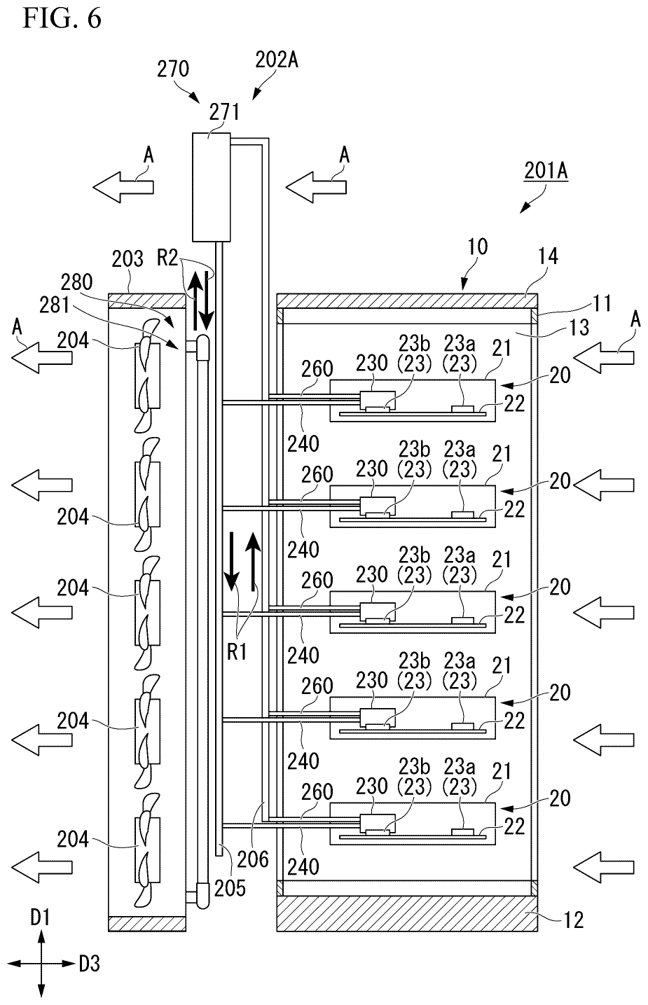

Next, a server cooling system 201A according to a first modification example of the second embodiment will be described with reference to FIG. 6.

As shown in FIG. 6, in the present modification example, as in the case of the first embodiment, a plurality of servers 20 are substantially equally arranged in the rack 10 in the up-down direction D1. For example, five servers 20 are disposed. In each modification example described below, the plurality of servers 20 are arranged as in the case of the first embodiment. In the cooling device 202A of the present modification example, the cooling unit 270 is positioned above the fan 204. The cooling unit 270 has a jacket 271 and a cooling coil (not shown) provided in the jacket 271. The refrigerant R1 is supplied to the jacket 271 from each refrigerant discharge path 260 through the second connection header 206.

In the jacket 271, the supplied refrigerant R1 is cooled by a cooling coil (not shown) inside the jacket 271 and air A outside the jacket 271.

According to the server cooling system 201A of the present modification example, the following operations and effects are exhibited.

In the present modification example, the cooling unit 270 is positioned above the fan 204.

According to the above-described configuration, the cooling unit 270 does not hinder the flow of the air A by the fan 204. Therefore, the server cooling system 201A can more efficiently air-cool the heat generating body 23. Further, since the noise caused by the driving of the fan 204 is reduced, the working environment is further improved.

### Second Modification Example of Second Embodiment

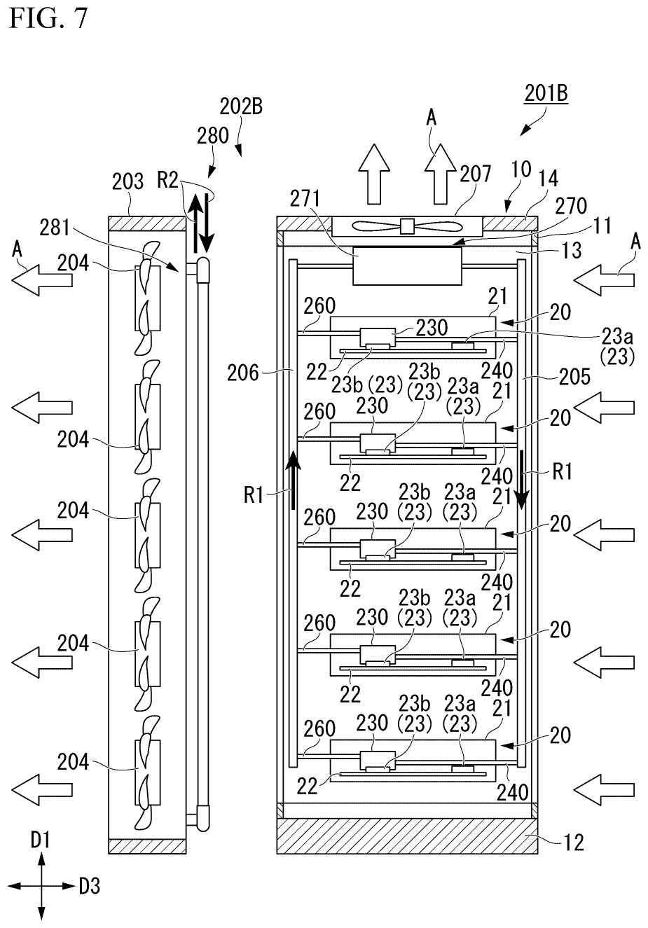

Next, a server cooling system 201B according to a second modification example of the second embodiment will be described with reference to FIG. 7.

As shown in FIG. 7, in the present modification example, the cooling device 202B further includes a second fan 207.

The second fan 207 is provided on the top plate 14 of the rack 10. The second fan 207 discharges the air A in the rack 10 upward.

The cooling unit 270 is provided in the rack 10 and above all the servers 20 in the rack 10. Further, the cooling unit 270 is provided below the second fan 207.

According to the server cooling system 201B of the present modification example, the following operations and effects are exhibited.

In the present modification example, the cooling device 202B includes the second fan 207. The second fan 207 is provided on the top plate 14 of the rack 10 and discharges the air A in the rack 10 upward. The cooling unit 270 is provided above all the servers 20 in the rack 10 and below the second fan 207.

According to the above configuration, the server cooling system 201B can send the air A to the jacket 271 of the cooling unit 270 by the second fan 207. The refrigerant R1 in the jacket 271 is cooled by the air A blown by the second fan 207. In addition, since the cooling unit 270 and the second fan 207 are provided in the rack 10, the cooling device 202B can be made compact. Therefore, it is possible to achieve the size reduction of the server cooling system 201B and to realize the space saving of the server cooling system 201B.

### Third Modification Example of Second Embodiment

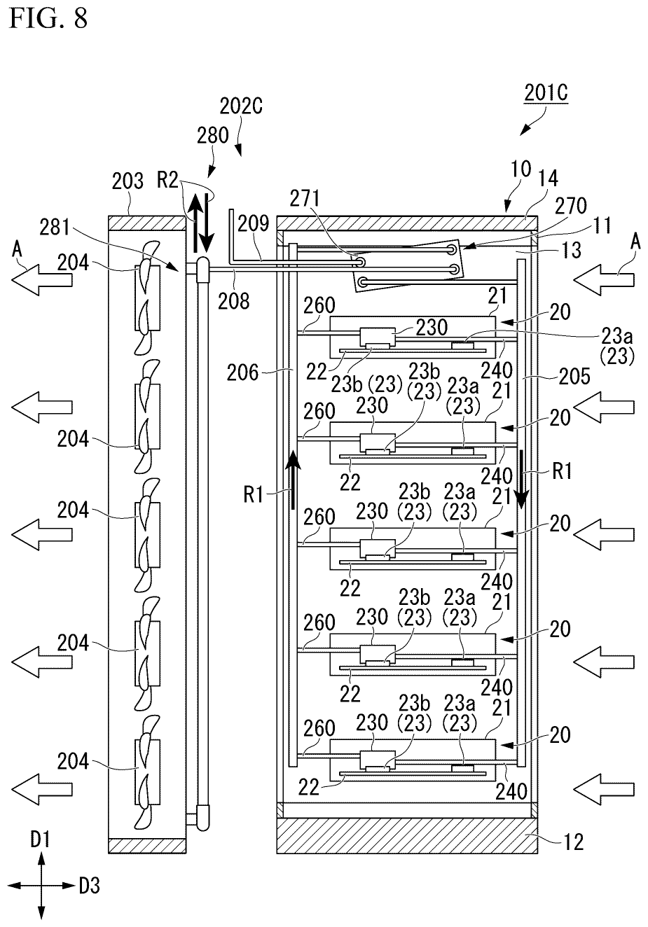

Next, a server cooling system 201C according to a third modification example of the second embodiment will be described with reference to FIG. 8.

As shown in FIG. 8, in the present modification example, the cooling unit 270 is provided in the rack 10 and above all the servers 20 in the rack 10. The cooling unit 270 is disposed to extend in the front-rear direction D3. The cooling unit 270 is disposed to be inclined. Therefore, the front end portion of the cooling unit 270 is positioned above the rear end portion of the cooling unit 270. The first connection header 205 is connected to a rear end portion of the cooling unit 270, and each second connection header 206 is connected to a front end portion of the cooling unit 270. The cooling unit 270 is, for example, a plate type heat exchanger.

The cooling device 202C further includes a supply communication pipe 208 and a discharge communication pipe 209.

The supply communication pipe 208 connects the cooling unit 270 and the cooling coil 281 of the second cooling unit 280 to each other. The supply communication pipe 208 communicates with the cooling coil 281 of the second cooling unit 280 to guide the second refrigerant R2 to the cooling unit 270.

The discharge communication pipe 209 is provided in the cooling unit 270. The discharge communication pipe 209 communicates with the cooling unit 270 and discharges the second refrigerant R2 from the cooling unit 270 to the outside of the cooling unit 270.

According to the server cooling system 201C of the present modification example, the following operations and effects are exhibited.

In the present modification example, the cooling unit 270 is provided above all the servers 20 in the rack 10. The cooling device 202C has a supply communication pipe 208 and a discharge communication pipe 209. The supply communication pipe 208 communicates with the second cooling unit 280 to guide the second refrigerant R2 to the cooling unit 270. The discharge communication pipe 209 communicates with the cooling unit 270 and discharges the second refrigerant R2 from the cooling unit 270.

According to the above configuration, the cooling unit 270 is provided above all the servers 20. Therefore, the cooling device 202C can be made compact by utilizing the dead space above the server 20.

In addition, the server cooling system 201C can guide the second refrigerant R2 of the cooling coil 281 to the cooling unit 270. As a result, the refrigerant R1 is cooled by heat exchange with the second refrigerant R2. Therefore, the configuration of the cooling unit 270 can be simplified. Therefore, the cooling device 202C can be designed to be more compact.

As described above, according to the present modification example, it is possible to achieve the size reduction of the server cooling system 201C and to realize the space saving of the server cooling system 201C.

In the present modification example, the cooling unit 270 is provided in the rack 10, but the present invention is not limited thereto. The cooling unit 270 may be provided outside the rack 10.

### Third Embodiment

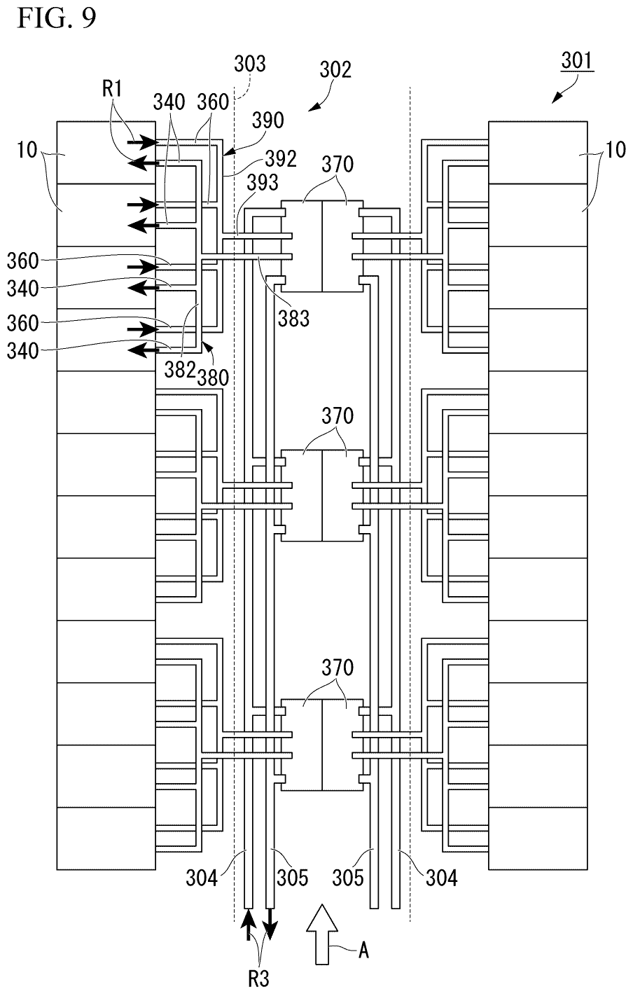

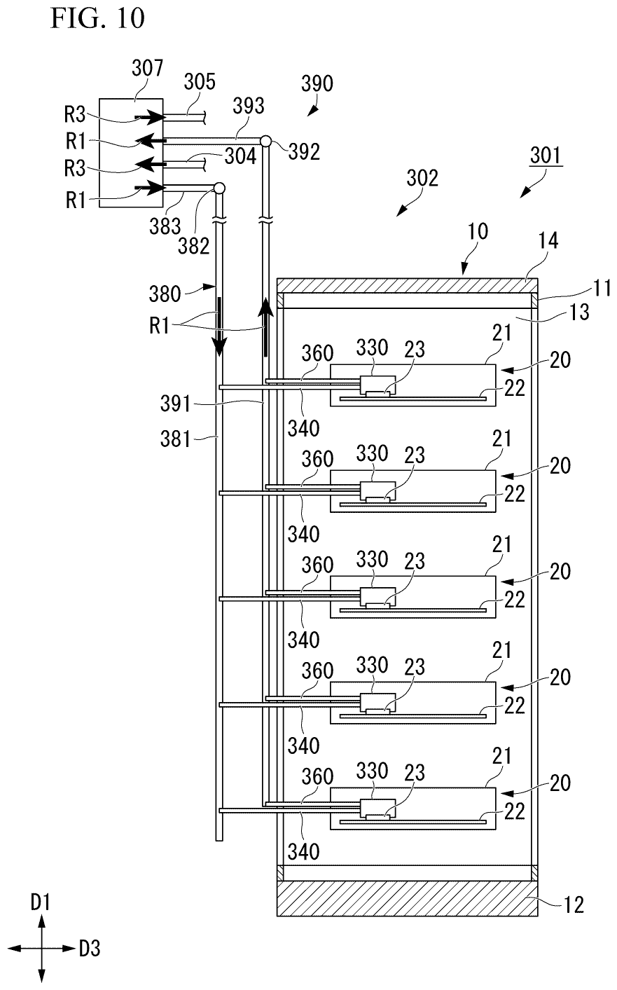

Hereinafter, a server cooling system 301 according to a third embodiment of the present disclosure will be described with reference to FIGS. 9 and 10. The same configurations as those in the first embodiment described above are designated by the same names and the same reference signs, and descriptions thereof will be appropriately omitted.

As shown in FIGS. 9 and 10, the server cooling system 301 of the present embodiment includes a rack 10, a duct 303, a plurality of servers 20, and a cooling device 302.

### Rack

A plurality of racks 10 are provided in the room to form a plurality of rows.

### Duct

The duct 303 is positioned above the rack 10. The duct 303 is positioned between the rows of the racks 10 and extends in a row along a horizontal surface. Air A flows inside the duct 303.

### Cooling Device

The cooling device 302 includes a cold plate 330, a refrigerant supply path 340, a refrigerant discharge path 360, a cooling unit 370, a distribution flow path 380, a collection flow path 390, a third refrigerant supply path 304, and a third refrigerant discharge path 305.

### Cold Plate

A plurality of cold plates 330 are provided to correspond to the heat generating bodies 23 of the respective servers 20. The cold plate 330 is in contact with the corresponding heat generating body 23.

### Refrigerant Supply Path

The refrigerant supply path 340 is provided for each server 20. The refrigerant supply path 340 is connected to each corresponding cold plate 330 and supplies the refrigerant R1 from the cooling unit 370 to each cold plate 330.

### Refrigerant Discharge Path

The refrigerant discharge path 360 is provided for each server 20. The refrigerant discharge path 360 is connected to each corresponding cold plate 330 and discharges the refrigerant R1 that has passed through each cold plate 330, to the cooling unit 370.

In addition, for one server 20, it is desirable that the connection port between the refrigerant discharge path 360 and the cold plate 330 is positioned above the connection port between the refrigerant supply path 340 and the cold plate 330.

### Cooling Unit

A plurality of cooling units 370 are provided in the duct 303. The number of cooling units 370 installed is smaller than the number of racks 10 installed. The cooling unit 370 cools heat generation of the server 20 in the plurality of racks 10.

### Distribution Flow Path

The distribution flow path 380 connects each refrigerant supply path 340 provided in each server 20 in the plurality of racks 10 to the cooling unit 370. The distribution flow path 380 distributes the refrigerant R1 cooled by the cooling unit 370 to each refrigerant supply path 340. The distribution flow path 380 has a first distribution line 381, a second distribution line 382, and a third distribution line 383.

The first distribution line 381 is provided for each rack 10. Each refrigerant supply path 340 extending from each server 20 in the corresponding rack 10 is connected to the first distribution line 381. The first distribution line 381 of the present embodiment extends in the up-down direction D1.

The second distribution line 382 communicates a plurality of the first distribution lines 381 with each other.

The third distribution line 383 connects the second distribution line 382 and the cooling unit 370.

### Collection Flow Path

The collection flow path 390 connects each refrigerant discharge path 360 provided in each server 20 in the plurality of racks 10 to one cooling unit 370. The collection flow path 390 collects the refrigerant R1 from each refrigerant discharge path 360 and guides the refrigerant R1 to one cooling unit 370. The collection flow path 390 has a first collection line 391, a second collection line 392, and a third collection line 393.

The first collection line 391 is provided for each rack 10. Each refrigerant discharge path 360 extending from each server 20 in the corresponding rack 10 is connected to the first collection line 391. The first collection line 391 of the present embodiment extends in the up-down direction D1.

The second collection line 392 communicates a plurality of first collection lines 391 with each other.

The third collection line 393 connects the second collection line 392 and the cooling unit 370.

### Third Refrigerant Supply Path

The third refrigerant supply path 304 supplies a third refrigerant R3 for cooling the refrigerant R1 to each cooling unit 370. The third refrigerant supply path 304 is provided in the duct 303. The third refrigerant supply path 304 extends in the extension direction of the duct 303.

### Third Refrigerant Supply Path

The third refrigerant discharge path 305 discharges the third refrigerant R3 from each cooling unit 370. The third refrigerant discharge path 305 is provided in the duct 303. The third refrigerant discharge path 305 extends in the extension direction of the duct 303.

### Circulation of Refrigerant

Next, the circulation of the refrigerant R1 in the server cooling system 301 will be described.

First, the refrigerant R1 of the cooling unit 370 is distributed to each refrigerant supply path 340 by the distribution flow path 380. The refrigerant R1 is supplied to the cold plate 330 connected to each refrigerant supply path 340. In the cold plate 330, the refrigerant R1 performs heat exchange with the heat generating body 23. As a result, the heat generating body 23 is cooled, and the refrigerant R1 is heated.

The refrigerant R1 that has passed through each cold plate 330 is collected from the refrigerant discharge path 260 to the collection flow path 390. Then, the refrigerant R1 is returned to the cooling unit 370.

In the cooling unit 370, heat exchange is performed by the refrigerant R1 and the third refrigerant R3. As a result, the refrigerant R1 heated by the cold plate 230 is cooled. The liquid phase refrigerant R1 in the cooling unit 370 is distributed again to each refrigerant supply path 340 through the distribution flow path 380. In this way, the refrigerant R1 circulates in the server cooling system 301.

### Operations and Effects

With the server cooling system 301 of the present embodiment, the following operations and effects are exhibited.

In the present embodiment, a plurality of racks 10 are provided. The cooling device 302 includes a distribution flow path 380 and a collection flow path 390. The distribution flow path 380 connects each refrigerant supply path 340 provided in each server 20 in the plurality of racks 10 to the cooling unit 370. The distribution flow path 380 distributes the refrigerant R1 cooled by the cooling unit 370 to each refrigerant supply path 340. The collection flow path 390 connects each refrigerant discharge path 360 provided in each server 20 in the plurality of racks 10 to one cooling unit 370. The collection flow path 390 collects the refrigerant R1 from each refrigerant discharge path 360 and guides the refrigerant R1 to one cooling unit 370.

According to the above configuration, the server cooling system 301 can collectively cool the heat generation of the servers 20 accommodated in the plurality of racks 10 by one cooling unit 370. Therefore, the cooling efficiency of the server cooling system 301 can be improved.

In the present embodiment, the server cooling system 301 further includes a duct 303. The duct 303 is positioned above the rack 10, and the air A flows inside the duct 303. The cooling unit 370 is provided in the duct 303.

According to the above configuration, even in a case where the refrigerant R1 leaks from the cooling unit 370, the refrigerant R1 does not flow into the server 20. Therefore, the server cooling system 301 can protect the server 20 from the leakage of the refrigerant R1.

In the present embodiment, the cooling device 302 has a third refrigerant supply path 304 and a third refrigerant discharge path 305. The third refrigerant supply path 304 supplies a third refrigerant R3 for cooling the refrigerant R1 to the cooling unit 370. The third refrigerant discharge path 305 discharges the third refrigerant R3 from the cooling unit 370.

According to the above configuration, the cooling unit 370 can cool the refrigerant R1 not only by the air A flowing in the duct 303 but also by the heat exchange between the third refrigerant R3 and the refrigerant R1. Therefore, the server cooling system 301 can satisfactorily cool the refrigerant R1. Further, according to the present embodiment, since the cooling unit 370 does not hinder the path of a person, the working environment is improved.

### First Modification Example of Third Embodiment

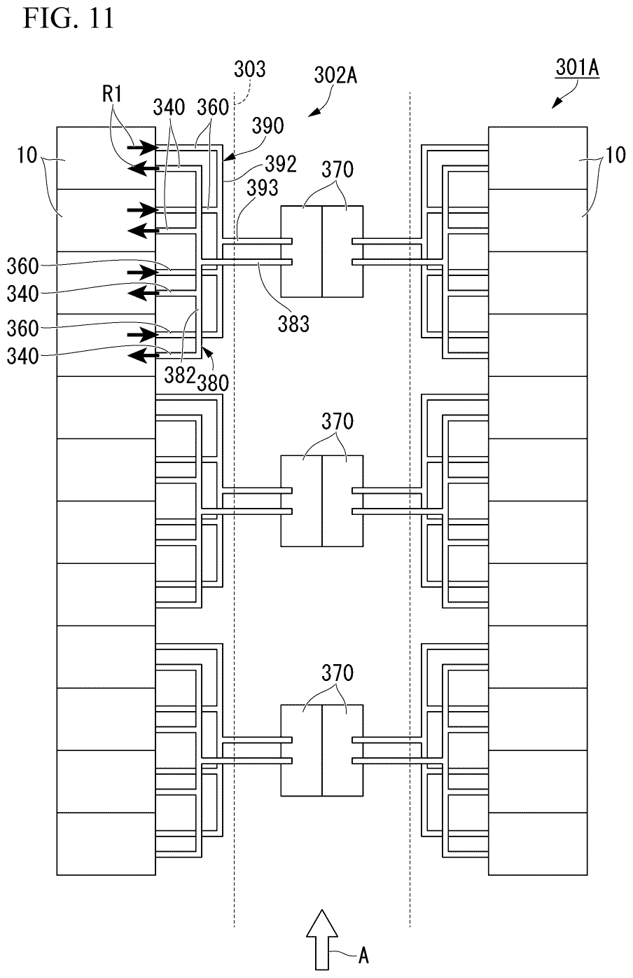

Next, a server cooling system 301A according to a first modification example of the third embodiment will be described with reference to FIG. 11.

As shown in FIG. 11, in the cooling device 302A of the present modification example, the cooling unit 370 cools the refrigerant R1 by the air A flowing in the duct 303. The cooling unit 370 of the present modification example is, for example, a fin tube type heat exchanger.

As a result, the refrigerant R1 is cooled only by the air A flowing in the duct 303. Therefore, the cooling unit 370 can be simplified. In addition, since the noise during the blowing is reduced as compared with the rear door method cooling in which a fan for air cooling is installed horizontally on the rack 10, the working environment is improved.

### Second Modification Example of Third Embodiment

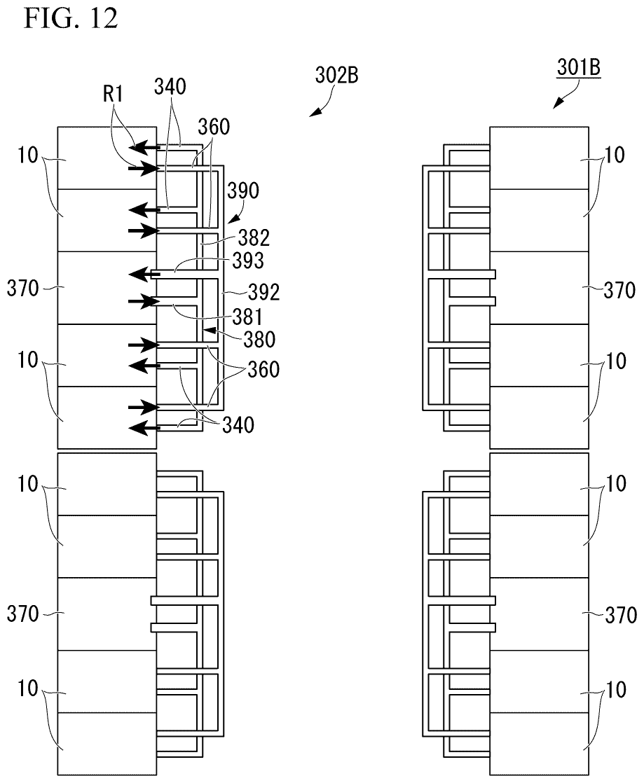

Next, a server cooling system 301B according to a second modification example of the third embodiment will be described with reference to FIG. 12.

As shown in FIG. 12, in the cooling device 302B of the present modification example, the cooling unit 370 is provided between the racks 10. An example of the cooling unit 370 is a vertically placed CDU.

Accordingly, the rack 10 and the cooling unit 370 can be efficiently disposed. Therefore, the layout of the server cooling system 301B is improved, and the working environment is improved.

### Other Embodiments

The embodiments of the present disclosure have been described above in detail with reference to the drawings. However, specific configurations are not limited to the embodiments, and include a design modification or the like within a scope which does not depart from the gist of the present disclosure.

### Appendix

The server cooling systems 1, 1A, 201, 201A, 201B, 201C, 301, 301A, and 301B described in each embodiment are understood as follows, for example.

(1) A server cooling system 1, 1A, 201, 201A, 201B, 201C, 301, 301A, and 301B according to a first aspect including: at least one rack 10; a plurality of servers 20 that are accommodated in the rack 10 to be arranged in an up-down direction D1 and each of which has a heat generating body 23; and a cooling device 2, 2A, 202, 202A, 202B, 202C, 302, 302A, and 302B that is configured to cool each of the heat generating bodies 23, in which the cooling device 2, 2A, 202, 202A, 202B, 202C, 302, 302A, and 302B includes a plurality of cold plates 30, 230, and 330 that are provided to correspond to the heat generating bodies 23 of each of the plurality of servers 20 and are in contact with the heat generating bodies 23 corresponding to each of the plurality of cold plates 30, 230, and 330, a plurality of refrigerant supply paths 40, 240, and 340 that are configured to supply a refrigerant R1 to each of the plurality of cold plates 30, 230, and 330, a plurality of refrigerant discharge paths 60, 260, and 360 that are configured to discharge the refrigerant R1 that has passed through each of the plurality of cold plates 30, 230, and 330, and a cooling unit 70, 270, and 370 that is configured to cool the refrigerant R1 that has passed through each of the plurality of refrigerant discharge paths 60, 260, and 360 and to introduce the refrigerant R1 into each of the plurality of refrigerant supply paths 40, 240, and 340.

The refrigerant R1 performs heat exchange with the heat generating body 23 in each of the cold plates 30, 230, and 330 and absorbs heat of the heat generating body 23. As a result, the heat generating body 23 is cooled, and the refrigerant R1 is heated. In the present aspect, the heated refrigerant R1 is guided to the cooling units 70, 270, and 370 through the refrigerant discharge paths 60, 260, and 360. The refrigerant R1 is cooled by the cooling units 70, 270, and 370 and is supplied again to each of the cold plates 30, 230, and 330 through the refrigerant supply paths 40, 240, and 340. As described above, the refrigerant R1 heated by each of the cold plates 30, 230, and 330 is collectively cooled by the cooling units 70, 270, and 370.

(2) The server cooling system 1 or 1A of the second aspect is the server cooling system 1 or 1A of the first aspect, in which each of the plurality of cold plates 30 is provided to be in contact with a plurality of the heat generating bodies 23, and the plurality of cold plates 30 may include a single-phase cold plate 30a in which the refrigerant R1 flows in a single-phase state, and a boiling cold plate 30b that is connected in series to the single-phase cold plate 30a in a direction in which the refrigerant R1 flows, and in which the refrigerant R1 boils and the refrigerant R1 flows in a two-phase state of a liquid phase and a gas phase.

With the above-described configuration, the cold plate 30 is in contact with the plurality of heat generating bodies 23. Therefore, the number of cold plates 30 can be reduced as compared with a case where one cold plate 30 is provided for each heat generating body 23. Further, the plurality of cold plates 30 include a single-phase cold plate 30a and a boiling cold plate 30b connected in series. As a result, the server cooling systems 1 and 1A can perform the heat exchange between the refrigerant R1 and the heat generating body 23 in a stepwise manner.

(3) The server cooling system 1 according to a third aspect is the server cooling system 1 according to the second aspect, in which the single-phase cold plate 30a is provided on a refrigerant supply path 40 side with respect to the boiling cold plate 30b, and the refrigerant R1 may flow in a liquid phase state in the single-phase cold plate 30a.

In the above configuration, in the single-phase cold plate 30a, the refrigerant R1 performs heat exchange with the heat generating body 23 in a liquid phase state. Thereafter, the refrigerant R1 passes through the single-phase cold plate 30a and is supplied to the boiling cold plate 30b. The refrigerant R1 receives heat from the heat generating body 23 in the boiling cold plate 30b, boils, and evaporates. As a result, in the boiling cold plate 30b, the heat of vaporization of the refrigerant R1 is taken away from the heat generating body 23, and thus the heat generating body 23 is strongly cooled.

(4) The server cooling system 1A of a fourth aspect is the server cooling system 1A of the second aspect, in which the single-phase cold plate 30a is provided on the refrigerant discharge path 60 side with respect to the boiling cold plate 30b, and the refrigerant R1 may flow in a gas phase state in the single-phase cold plate 30a.

In the above-described configuration, in the boiling cold plate 30b, the working fluid receives heat from the heat generating body 23, boils, and evaporates. Thereafter, the refrigerant R1 in the gas phase is supplied to the single-phase cold plate 30a. Therefore, the refrigerant R1 in a gas phase flows in the single-phase cold plate 30a. As a result, the refrigerant R1 flows at a high flow velocity in the single-phase cold plate 30a.

(5) The server cooling system 201, 201A, 201B, and 201C of the fifth aspect is the server cooling system 201, 201A, 201B, and 201C of the first aspect, in which the cooling device 202, 202A, 202B, and 202C includes a fan 204 that is installed in the at least one rack 10 and that is configured to draw in air to pass through the heat generating body 23, and a second cooling unit 280 that is provided between the at least one rack 10 and the fan 204 and that is configured to cool the air A that has passed through the heat generating body 23, and the second cooling unit 280 may include a cooling coil 281 through which a second refrigerant R2 that is configured to perform heat exchange with the air A around the second cooling unit 280 flows.

According to the above configuration, the server cooling systems 201, 201A, 201B, and 201C can draw in the air A by the fan 204 and pass the air A through the heat generating body 23. As a result, the server cooling systems 201, 201A, 201B, and 201C can cool the heat generating body 23 with both the refrigerant R1 in the cold plate 230 and the air A drawn in by the fan 204.

(6) The server cooling system 201 according to a sixth aspect is the server cooling system 201 according to the fifth aspect, in which the cooling unit 270 may be provided in the cooling coil 281 and may perform heat exchange between the refrigerant R1 and the second refrigerant R2.

According to the above configuration, the refrigerant R1 heated by performing heat exchange with the heat generating body 23 is cooled by the second refrigerant R2 in the cooling coil 281. Therefore, it is not necessary to separately provide a device for cooling the heated refrigerant R1.

(7) A server cooling system 201A according to a seventh aspect is the server cooling system 201A according to the fifth aspect, in which the cooling unit 270 may be positioned above the fan 204.

According to the above-described configuration, the cooling unit 270 does not hinder the flow of the air A by the fan 204.

(8) A server cooling system 201B according to an eighth aspect is the server cooling system 201B according to the fifth aspect, in which the cooling device 202B may include a second fan 207 that is provided on a top plate 14 of the at least one rack 10 and that is configured to discharge the air A in the at least one rack 10 upward, and the cooling unit 270 may be provided above all the plurality of servers 20 in the at least one rack 10 and below the second fan 207.

According to the above configuration, the server cooling system 201B can send the air A to the cooling unit 270 by the second fan 207. The refrigerant R1 in the cooling unit 270 is cooled by the air A blown by the second fan 207. In addition, since the cooling unit 270 and the second fan 207 are provided in the rack 10, the cooling device 202B can be made compact.

(9) A server cooling system 201C according to a ninth aspect is the server cooling system 201C according to the fifth aspect, in which the cooling unit 270 may be provided above all the plurality of servers 20, the cooling device 2 may include a supply communication pipe 208 that is configured to communicate with the second cooling unit 280 and guides the second refrigerant R2 to the cooling unit 270, and a discharge communication pipe 209 that is configured to communicate with the cooling unit 270 and discharges the second refrigerant R2 from the cooling unit 270.

According to the above configuration, the cooling unit 270 is provided above all the servers 20. Therefore, the cooling device 202C can be made compact by utilizing the dead space above the server 20.

In addition, the server cooling system 201C can guide the second refrigerant R2 of the cooling coil 281 to the cooling unit 270. As a result, the refrigerant R1 is cooled by heat exchange with the second refrigerant R2.

(10) The server cooling systems 301, 301A, and 301B of the tenth aspect are the server cooling systems 301, 301A, and 301B of the first aspect, in which the at least one rack has a plurality of the racks 10, and the cooling devices 302, 302A, and 302B may have a distribution flow path 380 that is configured to connect each of the plurality of refrigerant supply paths 340 provided in each of the plurality of servers 20 in the plurality of racks 10 to one cooling unit 370 and distributes the refrigerant R1 cooled by the one cooling unit 370 to each of the plurality of refrigerant supply paths 340, and a collection flow path 390 that is configured to connect each of the plurality of refrigerant discharge paths 360 provided in each of the plurality of servers 20 in the plurality of racks 10 to one cooling unit 370 and collects the refrigerant R1 from each of the plurality of refrigerant discharge paths 360 to guide the refrigerant R1 to the cooling unit 370.

According to the above configuration, the server cooling systems 301, 301A, and 301B can collectively cool the heat generation of the servers 20 accommodated in the plurality of racks 10 by one cooling unit 370.

(11) The server cooling systems 301 and 301A of an eleventh aspect are the server cooling system 301 and 301A of the tenth aspect, further including: a duct 303 that is positioned above the rack 10 and through which air A flows, in which the one cooling unit 370 may be provided in the duct 303.

According to the above configuration, even in a case where the refrigerant R1 leaks from the cooling unit 370, the refrigerant R1 does not flow into the server 20. Further, according to the present aspect, the cooling unit 370 does not hinder the path of a person.

(12) A server cooling system 301 according to a twelfth aspect is the server cooling system 301 according to the eleventh aspect, in which the cooling device 302 may include a third refrigerant supply path 304 that is configured to supply a third refrigerant R3 for cooling the refrigerant R1 to the one cooling unit 370, and a third refrigerant discharge path 305 that is configured to discharge the third refrigerant R3 from the one cooling unit 370.

According to the above configuration, the cooling unit 370 can cool the refrigerant R1 by heat exchange between the third refrigerant R3 and the refrigerant R1.

(13) A server cooling system 301A according to a thirteenth aspect is the server cooling system 301 A according to the eleventh aspect, in which the one cooling unit 370 may cool the refrigerant R1 with the air A flowing in the duct 303.

As a result, the refrigerant R1 is cooled only by the air A flowing in the duct 303. In addition, noise during blowing is reduced as compared with rear door cooling in which a fan for air cooling is installed horizontally on the rack 10.

(14) A server cooling system 301B according to a fourteenth aspect is the server cooling system 301B according to the tenth aspect, in which the one cooling unit 370 may be provided between the plurality of racks 10.

Accordingly, the rack 10 and the cooling unit 370 can be efficiently disposed.

### INDUSTRIAL APPLICABILITY

According to the server cooling system of the present disclosure, it is possible to efficiently cool the heat generating body while achieving compactness.

### REFERENCE SIGNS LIST

1 . . . Server cooling system 2 . . . Cooling device 10 . . . Rack 11 . . . Frame 12 . . . Bottom plate 13 . . . Side plate 14 . . . Top plate 20 . . . Server 21 . . . Casing 22 . . . Substrate 23 . . . Heat generating body 23a. . . Low-temperature heat generating body 23b. . . High-temperature heat generating body 24 . . . Ventilation hole 30 . . . Cold plate 30a. . . Single-phase cold plate 30b. . . Boiling cold plate 40 . . . Refrigerant supply path 41 . . . Refrigerant supply header 42 . . . Refrigerant supply branch pipe 50 . . . Refrigerant connection path 60 . . . Refrigerant discharge path 61 . . . Refrigerant discharge header 62 . . . Refrigerant discharge branch pipe 70 . . . cooling unit 71 . . . cooling unit casing 72 . . . Heat exchanger 73 . . . First main header 74 . . . First connecting pipe 75 . . . Second main header 76 . . . Second connecting pipe 77 . . . Pump 1A . . . Server cooling system 2A . . . Cooling device 201 . . . Server cooling system 202 . . . Cooling device 203 . . . Fan casing 204 . . . Fan 205 . . . First connection header 206 . . . Second connection header 230 . . . Cold plate 240 . . . Refrigerant supply path 260 . . . Refrigerant discharge path 270 . . . cooling unit 271 . . . Jacket 280 . . . Second cooling unit 281 . . . Cooling coil 201A . . . Server cooling system 202A . . . Cooling device 201B . . . Server cooling system 202B . . . Cooling device 207 . . . Second fan 201C . . . Server cooling system 202C . . . Cooling device 208 . . . Supply communication pipe 209 . . . Discharge communication pipe 301 . . . Server cooling system 302 . . . Cooling device 303 . . . Duct 304 . . . Third refrigerant supply path 305 . . . Third refrigerant discharge path 330 . . . Cold plate 340 . . . Refrigerant supply path 360 . . . Refrigerant discharge path 370 . . . cooling unit 380 . . . Distribution flow path 381 . . . First distribution line 382 . . . Second distribution line 383 . . . Third distribution line 390 . . . Collection flow path 391 . . . First collection line 392 . . . Second collection line 393 . . . Third collection line 301A . . . Server cooling system 302A . . . Cooling device 301B . . . Server cooling system 302B . . . Cooling device A . . . Air D1 . . . Up-down direction D2 . . . Left-right direction D3 . . . Front-rear direction R1 . . . Refrigerant R2 . . . Second refrigerant R3 . . . Third refrigerant W . . . Cooling water

1.-14. (canceled)

15. A server cooling system comprising:
at least one rack;
a plurality of servers that are accommodated in the rack to be arranged in an up-down direction and each of which has a heat generating body; and
a cooling device that is configured to cool each of the heat generating bodies, wherein the cooling device includes
a plurality of cold plates that are provided to correspond to the heat generating bodies of each of the plurality of servers and are in contact with the heat generating bodies corresponding to each of the plurality of cold plates,
a plurality of refrigerant supply paths that are configured to supply a refrigerant to each of the plurality of cold plates,
a plurality of refrigerant discharge paths that are configured to discharge the refrigerant that has passed through each of the plurality of cold plates,
a cooling unit that is configured to cool the refrigerant that has passed through each of the plurality of refrigerant discharge paths and to introduce the refrigerant into each of the plurality of refrigerant supply paths,
each of the plurality of cold plates is provided to be in contact with a plurality of the heat generating bodies, and
the plurality of cold plates include
a single-phase cold plate in which the refrigerant flows in a single-phase state, and
a boiling cold plate that is connected in series to the single-phase cold plate in a direction in which the refrigerant flows, and in which the refrigerant boils and the refrigerant flows in a two-phase state of a liquid phase and a gas phase.

16. The server cooling system according to claim 15, wherein the single-phase cold plate is provided on a refrigerant supply path side with respect to the boiling cold plate, and the refrigerant flows in a liquid phase state in the single-phase cold plate.

17. The server cooling system according to claim 15, wherein the single-phase cold plate is provided on a refrigerant discharge path side with respect to the boiling cold plate, and the refrigerant flows in a gas phase state in the single-phase cold plate.

18. A server cooling system comprising:
at least one rack;
a plurality of servers that are accommodated in the rack to be arranged in an up-down direction and each of which has a heat generating body; and
a cooling device that is configured to cool each of the heat generating bodies, wherein the cooling device includes
a plurality of cold plates that are provided to correspond to the heat generating bodies of each of the plurality of servers and are in contact with the heat generating bodies corresponding to each of the plurality of cold plates,
a plurality of refrigerant supply paths that are configured to supply a refrigerant to each of the plurality of cold plates,
a plurality of refrigerant discharge paths that are configured to discharge the refrigerant that has passed through each of the plurality of cold plates,
a cooling unit that is configured to cool the refrigerant that has passed through each of
the plurality of refrigerant discharge paths and to introduce the refrigerant into each of the plurality of refrigerant supply paths,
the cooling device includes
a fan that is installed in the at least one rack and that is configured to draw in air to pass through the heat generating body, and
a second cooling unit that is provided between the at least one rack and the fan and that is configured to cool the air that has passed through the heat generating body, and
the second cooling unit includes a cooling coil through which a second refrigerant that performs heat exchange with air around the second cooling unit flows.

19. The server cooling system according to claim 18, wherein the cooling unit is provided in the cooling coil and is configured to perform heat exchange between the refrigerant and the second refrigerant.

20. The server cooling system according to claim 18, wherein the cooling unit is positioned above the fan.

21. The server cooling system according to claim 18,
wherein the cooling device includes a second fan that is provided on a top plate of the at least one rack and that is configured to discharge the air in the at least one rack upward, and
the cooling unit is provided above all the plurality of servers in the at least one rack and below the second fan.

22. The server cooling system according to claim 18,
wherein the cooling unit is provided above all the plurality of servers,
the cooling device includes
a supply communication pipe that is configured to communicate with the second cooling unit and guide the second refrigerant to the cooling unit, and
a discharge communication pipe that is configured to communicate with the cooling unit and discharge the second refrigerant from the cooling unit.

23. A server cooling system comprising:
at least one rack;
a plurality of servers that are accommodated in the rack to be arranged in an up-down direction and each of which has a heat generating body; and
a cooling device that is configured to cool each of the heat generating bodies, wherein the cooling device includes
a plurality of cold plates that are provided to correspond to the heat generating bodies of each of the plurality of servers and are in contact with the heat generating bodies corresponding to each of the plurality of cold plates,
a plurality of refrigerant supply paths that are configured to supply a refrigerant to each of the plurality of cold plates,
a plurality of refrigerant discharge paths that are configured to discharge the refrigerant that has passed through each of the plurality of cold plates,
a cooling unit that is configured to cool the refrigerant that has passed through each of the plurality of refrigerant discharge paths and to introduce the refrigerant into each of the plurality of refrigerant supply paths,
the at least one rack has a plurality of racks,
the cooling device includes
a distribution flow path that is configured to connect each of the plurality of refrigerant supply paths provided in each of the plurality of servers in the plurality of racks to one cooling unit and distribute the refrigerant cooled by the one cooling unit to each of the plurality of refrigerant supply paths, and
a collection flow path that is configured to connect each of the plurality of refrigerant discharge paths provided in each of the plurality of servers in the plurality of racks to one cooling unit and collect the refrigerant from each of the plurality of refrigerant discharge paths to guide the refrigerant to the one cooling unit.

24. The server cooling system according to claim 23, further comprising:
a duct that is positioned above the rack and through which air flows,
wherein the one cooling unit is provided in the duct.

25. The server cooling system according to claim 24,
wherein the cooling device includes
a third refrigerant supply path that is configured to supply a third refrigerant for cooling the refrigerant to the one cooling unit, and
a third refrigerant discharge path that is configured to discharge the third refrigerant from the one cooling unit.

26. The server cooling system according to claim 24, wherein the one cooling unit cools the refrigerant with the air flowing in the duct.

27. The server cooling system according to claim 23, wherein the one cooling unit is provided between the plurality of racks.
